(19) United States
(12) Patent Application Publication
(10) Pub. No.: US 2026/0268125 A1
(43) Pub. Date: Sep. 10, 2026

(54) DESIGNING EFFICIENT LOGIC CIRCUITS USING MACHINE LEARNING

(71) Applicant: GDM Holding LLC, Mountain View, CA (US)

(72) Inventors: Adam Connor Slavin Hillier, London (GB); Georges Henri Joseph Rotival, Paris (FR); Ivan Lobov, St. Albans (GB); Marco Oreste Gelmi, London (GB); Kshiteej Sharad Mahajan, Los Altos, CA (US); Vinod Nair, London (GB); Sergio Guadarrama Cotado, Berkeley, CA (US); Olivier Temam, Antony (FR); Thuy Ngan Vu, London (GB)

(21) Appl. No.: 19/489,150

(22) PCT Filed: Jun. 3, 2024
(86) PCT No.: PCT/EP2024/065239

§ 371 Date: Dec. 1, 2025

Related U.S. Application Data
(60) Provisional application No. 63/470,436, filed on Jun. 1, 2023.

(51) Int. Cl. G06N 3/0475; G06N 3/084

(52) U.S. Cl. CPC G06N 3/0475; G06N 3/084

(57) ABSTRACT

Systems and methods for designing a logic circuit For example, the logic circuit can be designed by training a circuit neural network that represents the circuit.

### CROSS-REFERENCE TO RELATED APPLICATIONS

This application claims the benefit of U.S. Provisional Patent Application No. 63/470,436, filed on Jun. 1, 2023, the contents of which are hereby incorporated by reference.

### BACKGROUND

This specification relates to designing logic circuits using machine learning.

### SUMMARY

This specification describes a system implemented as computer programs on one or more computers in one or more locations that receives a specification for a logic circuit and, in response, generates a design for the logic circuit.

Particular embodiments of the subject matter described in this specification can be implemented so as to realize one or more of the following advantages.

Logic circuits are fundamental components of all digital circuits and systems. The design of logic circuits to carry out a specified function is therefore an essential part of computer chip design.

In more detail, logic synthesis is the problem of designing a circuit composed of logic gates (e.g., AND, OR, etc.) from an abstract specification of a function (e.g., a truth table) that the circuit should implement. Logic synthesis is how the basic building blocks of modern chips are designed, and is therefore one of the fundamental problems of modern chip design. In addition to fidelity to the specification, logic synthesis must also take into account the efficiency of the design when implemented in hardware. For example, hardware properties such as power, performance, and area (abbreviated as PPA) must be taken into consideration in order to design a circuit that can be fabricated as part of a computer chip. Thus, by more effectively designing a logic circuit, i.e., by designing a more efficient logic circuit, the system can improve the performance of the final, fabricated computer chip in many respects: (i) the system can improve the accuracy of the computer chip in generating correct outputs and (ii) the system can significantly improve the efficiency of the computer chip, e.g., by reducing the area, power, or both consumed by the chip.

This specification describes addressing this problem, i.e., the problem of designing a more efficient logic circuit, using machine learning. In particular, this specification describes a machine learning technique for designing a circuit that optimizes the correctness of the circuit with respect to the specification. More specifically, by making use of the described circuit neural network to represent the logic circuit and then generating a design for the circuit by training the neural network, the described techniques can effectively use gradient descent to “learn” a design that optimizes correctness, without relying on heuristics or manually engineered rules.

In some cases, because the system trains a circuit neural network on randomly sampled batches of training examples, e.g., of rows of the truth table given by the specification, the specification received by the system need not be complete, allowing the system to be more flexibly deployed in situations where existing techniques would fail, e.g., in situations where the system has only limited available information regarding the types of inputs that the logic circuit will need to process after fabrication.

Once the correctness has been optimized, the described techniques can then optimize the efficiency of the initial design while maintaining functional equivalence with respect to the initial design, resulting in a final design that is both efficient, e.g., in terms of power, performance, and area, while maintaining optimized correctness.

Additionally, by varying the architecture and hyperparameters of the circuit neural network, by varying the efficiency objective to optimize, or both, the system can automatically generate a broad and diverse set of designs. This can give a chip designer or other component of electronic design automation (EDA) software tool many different high-quality options to consider when designing a computer chip.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 shows an example circuit design system.

FIG. 2 shows an example circuit neural network.

FIG. 3 is a flow diagram of an example process for generating a design for a logic circuit.

FIG. 4 is a flow diagram of an example process for training the circuit neural network.

FIG. 5 is a flow diagram of an example process for generating multiple designs for a logic circuit.

Like reference numbers and designations in the various drawings indicate like elements.

### DETAILED DESCRIPTION

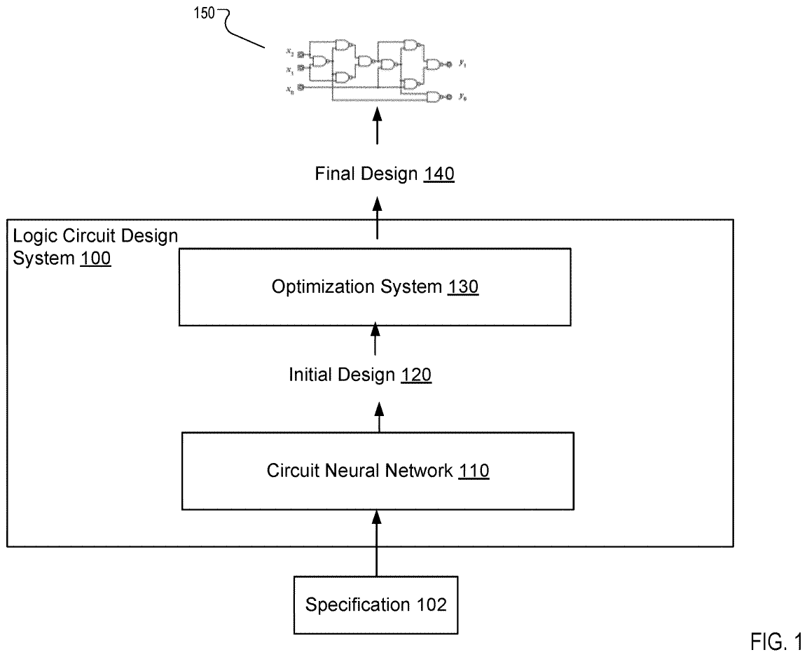

FIG. 1 shows an example circuit design system 100. The circuit design system 100 is an example of a system implemented as computer programs on one or more computers in one or more locations, in which the systems, components, and techniques described below can be implemented.

The system 100 receives a specification 102 for a logic circuit 150 and, in response, generates a design for the logic circuit 150.

A logic circuit is a collection of multiple, interconnected logic gates. That is, within the circuit, each logic gate is connected to one or more of: the inputs to the logic circuit, one or more other gates within logic circuit, or the outputs of the logic circuit.

A logic gate is a device, e.g., an electronic device, that performs a corresponding logical operation on a set of one or more inputs to produce a set of one or more outputs.

The logical operation that is performed by a logic gate is determined by the type of the logic gate.

Examples of types of logic gates include buffer gates, NOT gates (or inverter gates), AND gates, OR gates, NAND gates, NOR gates, XOR gates, XNOR gates, complementary gates, tri-state gates, and so on.

The specification 102 specifies requirements to be satisfied by the logic circuit 150.

For example, the specification 102 can define a truth table for the logic circuit 150. The truth table includes multiple rows, each of which specifies (i) a set of inputs (“circuit inputs”) to the logic circuit, e.g., a set of input binary values and (ii) a ground truth set of outputs (“circuit outputs”) that should be generated by the logic circuit 150 by processing the set of inputs, e.g., a set of ground truth output binary values.

Thus, in this example, the specification 102 includes multiple input-output pairs, where each pair includes (i) a set of inputs (“circuit inputs”) to the logic circuit, e.g., a set of input binary values and (ii) a ground truth set of outputs (“circuit outputs”) that should be generated by the logic circuit 150 by processing the set of inputs.

In some cases, the specification 102 also specifies other requirements for the logic circuit, e.g., constraints on the area consumed by the logic circuit 150 on the surface of a computer chip, constraints on the power consumed by the logic circuit 150, constraints on the performance, e.g., in terms of latency or other performance measure, of the logic circuit 150, and so on.

More generally, the specification 102 can specify an objective that the design of the logic circuit 150 should optimize, e.g., that quantifies the importance of various properties of a circuit that has been fabricated according to the design.

For example, the objective can be a PPA (power performance and area) objective that assigns respective weights to the power, performance, and the area consumed by a logic circuit 150 fabricated according to the design. Alternatively, the PPA objective can be a constrained objective that identifies one property to maximize (or minimize) subject to constraints on one or more other properties.

Once the system 100 has generated the design, the system can fabricate an integrated circuit or other electrical component that includes a logic circuit 150 that has the design (using any conventional chip fabrication technique) or provide data specifying the design to another system for use in fabricating the logic circuit 150. For example, the system 100 may generate instructions configured to cause the system 100, or another system, to fabricate the integrated circuit, or other electrical component, that includes the logic circuit 150 that has the design.

In some examples, the system 100 can be part of an electronic design automation (EDA) software tool and can receive the specification 102 from a user of the tool or from another component of the tool. In this example, the system 100 can provide the design for evaluation by another component of the EDA software tool before the computer chip is fabricated.

To generate the design after receiving the specification 102 for the logic circuit, the system 100 initializes a circuit neural network 110.

The circuit neural network 110 includes a sequence of layers, with each layer having one or more nodes, and each node in each layer representing a respective logic gate that has one or more input ports and one or more output ports.

As part of initializing the circuit neural network 110, the system 100 initializes, for each node, a respective probability distribution over a respective set of input connections for each input port of the respective logic gate represented by the node.

The respective set of input connections for a given logic gate is a set of other components that can be connected to the input port within the logic circuit.

For example, for a given node, the set of input connections for a given logic gate can include the inputs to the logic circuit, one or more output ports of one or more other logic cates represented by other nodes in the neural network, or both. The probability distribution over the set of input connections assigns a respective probability to each input connection in the set that represents the likelihood that the input connection will be selected to be connected to the input port within the logic circuit.

For example, the respective probability distribution for any give node can be initialized to a uniform distribution across the respective set of input connections for the given node or a randomly sampled distribution.

During the processing of a set of inputs using the circuit neural network 110, each node receives a respective input for each input port of the logic gate represented by the node. That is, when the input port is connected to one of the circuit inputs, the node receives the circuit input. When the input port is connected to the output port of another logic gate, the node receives an output generated by the other node representing the other logic gate during the processing of the set of inputs.

Each node then applies, to the received input(s), a respective function that represents the logic operation performed by the logic gate represented by the node to generate a respective output for each of the output ports of the logic gate represented by the node.

Thus, by processing the set of inputs through the circuit neural network 110 in accordance with the current connectivity between the nodes, the system 100 generates an output that would be generated by the logic circuit 150 if the logic gates represented by the nodes were connected according to the current connectivity.

In some implementations, the system 100 receives initialization data that specifies the number of layers in the circuit neural network, the number of nodes in each layer, and the respective gate type for each logic gate represented by each of the nodes of the circuit neural network. In these cases, the system can initialize the neural network 110 with an architecture that matches that specified in the received data, i.e., by initializing the circuit neural network to have the specified number of layers, the specified number of nodes in each layer, and with each node in each layer representing a logic gate having the respective specified gate type for the logic gate.

In some other implementations, the system 100 can determine the architecture of the neural network 110, e.g., can randomly select an architecture that conforms to the specification 102 or can select a predetermined architecture. As will be described below, in some cases, the system can initialize multiple different architectures for the neural network that each conform to the specification 102 but that have different numbers or configurations of nodes, that have nodes representing different types of logic gates, and so on.

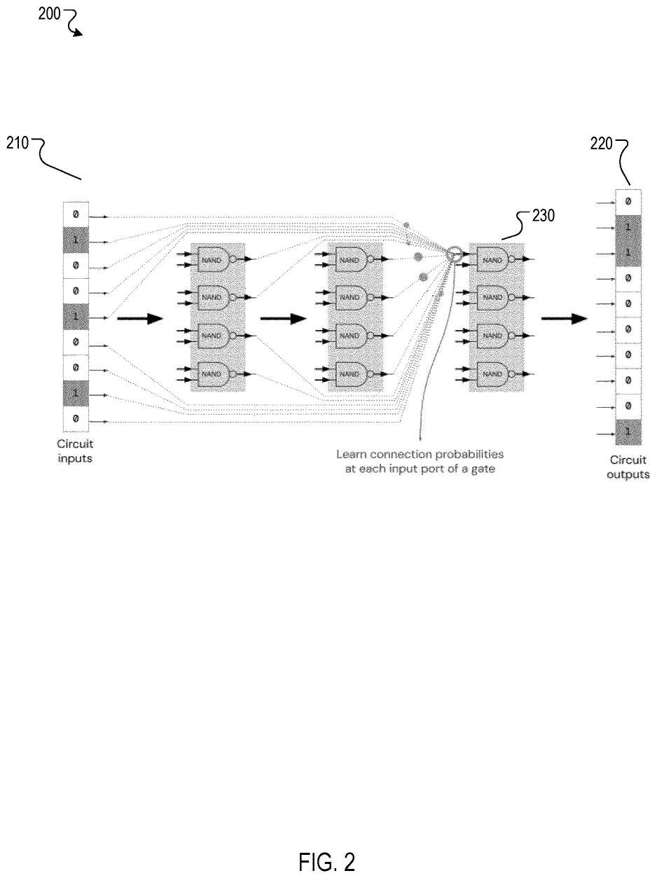

FIG. 2 shows an example 200 of a circuit neural network 110.

As shown in FIG. 2, the circuit neural network 110 is connected to a set of circuit inputs 210 and generates as output a set of circuit outputs 220. The number of values in the circuit inputs and circuit outputs, i.e., the format of the inputs to and outputs of the logic circuit 150, can be specified as part of the specification 102.

In the example 200, the circuit neural network 110 has three layers, each of which includes four nodes. Each node represents a respective logic gate within the logic circuit and each logic gate, in turn, has a respective type.

In the example 200, all of the nodes represent NAND gates but, more generally, the logic gate represented by any given node can be any particular type of logic gate, e.g., with different nodes representing different types of logic gates from one another or all of the nodes representing a given type of logic gate that is not a NAND gate.

During operation, each node is configured to perform the logic operation of the logic gate represented by the node. However, because the operations performed by logic gates are generally “hard” operations that are not differentiable, each node in the neural network 110 performs a continuous function that expresses the respective logic operation performed by the respective logic gate to generate an output. For example, the operations of a NAND gate, i.e., a gate that performs z=NAND(x, y), can be expressed as a continuous function z=(1−x)*y+x*(1−y) for x, y, z∈ [0,1]). Other types of logic gates can similarly be represented by continuous functions rather than by hard logic operations. This allows the system to train the neural network by gradient descent, as will be described below.

The system can determine the set of input connections for the input ports of the gates represented by nodes in any of a variety of ways.

For example, in the example 200, the layers are arranged in a sequence. For each node in the first layer of the sequence of layers, the respective set of input connections for the logic gate represented by the node includes each of the set of circuit inputs to the logic circuit.

Moreover, for each node in each layer after the first layer of the sequence of layers, the respective set of input connections for the logic gate represented by the node includes the output ports of the respective logic gates represented by each node in one or more layers that precede the layer in the sequence. In the example 200, for each node in each layer after the first layer of the sequence of layers, the respective set of input connections for the logic gate represented by the node include each of the set of circuit inputs to the logic circuit.

However, in other examples, the set of input connections can be selected differently and the layers of the neural network can be arranged differently, e.g., in a directed graph with more complex connectivity.

In particular, the example 200 shows the set of input connections for one of the input ports of a node 230. As can be seen from the example, the set of input connections includes all of the circuit inputs 210 and all of the output ports of all nodes in the layers preceding the layer of the node 230.

At initialization, each of these input connections is associated with a respective probability.

After initialization, the system 100 then trains the circuit neural network 110 using the specification 102 to update the respective probability distributions for the input ports of the logic gates represented by the nodes of the neural network. That is, during the training of the circuit neural network 110, the system treats the probability distributions associated with each of the nodes as the learnable parameters of the neural network 110 and repeatedly updates these parameters by performing an iterative training technique using the specification 102. For example, as shown in the example 200, the system 100 learns the connection probabilities of the set of input connections for the input port of the node 230.

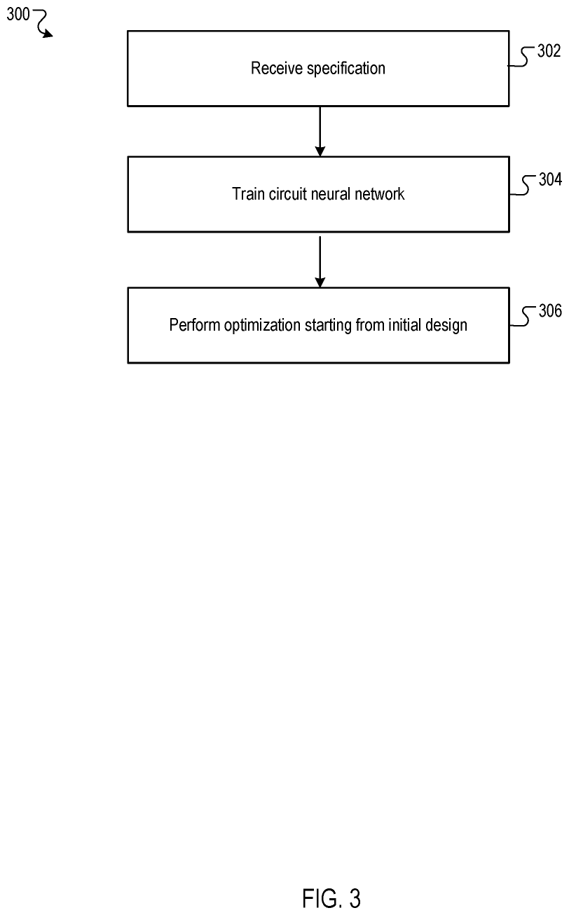

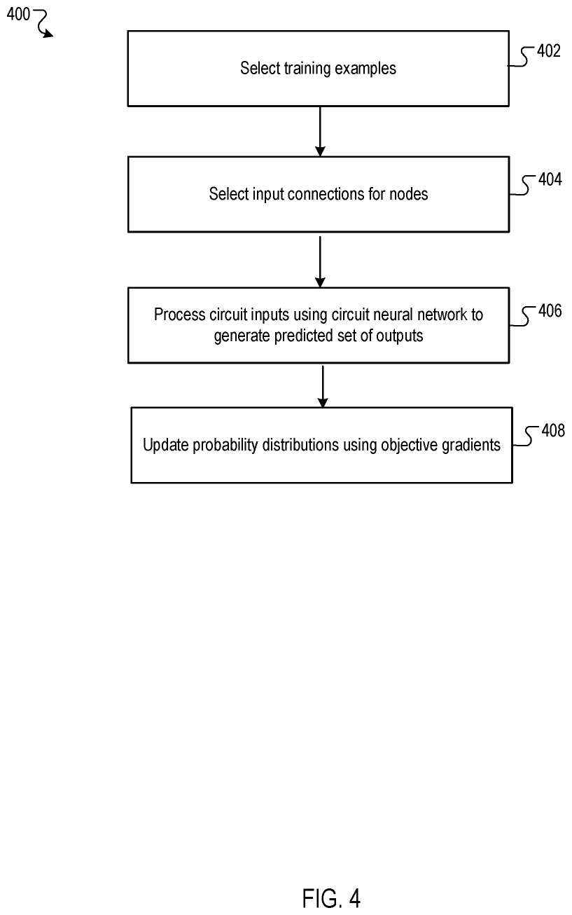

Training the neural network 110 will be described in more detail below with reference to FIGS. 3 and 4.

Returning to the description of FIG. 1, after the training is completed, the system 100 determines, based on the updated probability distributions for the nodes of the neural network 110, an initial design 120 for the logic circuit 150 that satisfies at least part of the specification 102 of the logic circuit.

In particular, the system 100 can generate the initial design 120 by, for each input port of each logic gate, selecting, as the input connection for the respective logic gate in the initial design, the input connection from the respective set of input connections that has a highest probability in the updated probability distribution for the input port. In other words, for each input port, the system selects the argmax input connection.

For example, when the specification 102 defines both a truth table and other requirements for the logic circuit, generating the initial design 120 as described above can result in an initial design 120 that satisfies the requirements of the truth table.

Optionally, the system 100 can then generate a final design 140 from the initial design 120.

For example, an optimization system 130 within the system 100 can perform an optimization of an objective starting from the initial design. Performing this optimization can result in a final design 140 that still satisfies the requirements of the truth table but that improves the efficiency of the initial design 120 with respect to the hardware performance characteristics that are of interest. For example, the objective can be specified in the specification 102 as indicated above or can be generated by the system 100.

Performing the optimization will be described in more detail below with reference to FIG. 3.

FIG. 3 is a flow diagram of an example process 300 for generating a design for a logic circuit. For convenience, the process 300 will be described as being performed by a system of one or more computers located in one or more locations. For example, a circuit design system, e.g., the circuit design system 100 of FIG. 1, appropriately programmed, can perform the process 300.

The system receives a specification for a logic circuit (step 302).

The system then initializes a circuit neural network. In particular, as described above, the system initializes the circuit neural network to include a sequence of layers. Each layer of the neural network has one or more nodes, each node in each layer representing a respective logic gate that has one or more input ports and one or more output ports. As part of the initializing, for each node, the system initializes a respective probability distribution over a respective set of input connections for each input port of the respective logic gate represented by the node.

The system trains the circuit neural network using the specification to update the respective probability distributions for the input ports of the logic gates represented by the nodes of the neural network (step 304).

This training will be described below with reference to FIG. 4.

After training, the system determines, based on the updated probability distributions for the nodes of the neural network, an initial design for the logic circuit that satisfies the specification of the logic circuit. In particular, as described above, for each input port, the system can select the argmax input connection to the input to the input port in the initial design. If any given node generates an output that is not selected as an input for any input port, the system can remove that given node from the initial design.

Optionally, the system then generates a final design from the initial design (step 306).

For example, the system can perform an optimization of an objective starting from the initial design. Performing this optimization can result in a final design that still satisfies the requirements of the truth table but that improves the efficiency of the initial design with respect to the hardware performance characteristics that are of interest. For example, the objective can be specified in the specification as indicated above or can be generated by the system.

To perform the optimization, the system can optimize over sequences of rewrite actions applied to the initial design. Each rewrite action applies a respective modification to the current design in order to update the design. More specifically, a rewrite action is an action that, when applied to a current logic circuit, modifies one or more of the logic gates in the current logic circuit while yielding a modified logic circuit that maintains functional equivalence with the current logic circuit, i.e., that modifies the current logic circuit without modifying the output that will be generated by the current logic circuit by processing any given input in the truth table.

Examples of rewrite actions can be, e.g., any or all of those supported by the ABC: A System for Sequential Synthesis and Verification open source software package and described at https://people.eecs.berkeley.edu/~alanmi/abc/ under the “Command Summary” section.

To optimize over sequences of rewrite actions, the system searches through a space of sequences of rewrite actions, i.e., of sequences that each include one or more rewrite actions applied one after the other, to identify an optimized sequence of actions, i.e., a sequence that, starting from the initial design, results in a final design that optimizes the objective.

The system can perform this optimization, i.e., the search through the space, using any appropriate optimization technique.

For example, the system can perform the optimization using one of: simulated annealing, a genetic algorithm, or Bayesian optimization.

As another example, the system can perform the optimization by performing a tree search over a state tree of states of the design that is traversed by performing rewrite actions on the design. As an example, the tree search can be a Monte Carlo Tree Search (MCTS).

As one example of this, the tree search can be guided by outputs of a neural network that, at any given point during the search, receives an input that includes a current state of the design and generates an output that include a probability distribution over a set of possible rewrite actions that can be applied when the design is in the current state. One example of such a search technique is described in Silver, et al, Mastering Chess and Shogi by Self-Play with a General Reinforcement Learning Algorithm.

Because the rewrite actions maintain functional equivalence with the initial design, as a result of the optimization, the system can generate a final design that has functional equivalence with the initial design, but performs better with respect to the objective being optimized.

Once the system has performed the optimization to generate the final design, the system can output the final design as described above. As optimization of the initial design is optional, if optimization is not performed the generated final design may be identical to the initial design. That is, the generation of the final design may be to designate the initial design as the final design where optimization does not take place.

FIG. 4 is a flow diagram of an example process 400 for training the circuit neural network. For convenience, the process 400 will be described as being performed by a system of one or more computers located in one or more locations. For example, a circuit design system, e.g., the circuit design system 100 of FIG. 1, appropriately programmed, can perform the process 400.

The system can perform the training across multiple training iterations. At each training iteration, the system can update the probability distributions for some or all of the input ports of some or all of the nodes in the circuit neural network by performing the process 400.

The system selects, using the specification, one or more training examples (step 402). Each training example includes a training set of circuit inputs and a target set of circuit outputs. For example, the system can select the one or more training examples by randomly sampling a fixed number of rows from the truth table.

The system then performs steps 404 and 406 for each training example.

The system selects, for each node and for each input port of the respective logic gate represented by the node, an input connection from the respective set of input connections for the input port using the probability distribution for the input port (step 404).

As described above, the system performs the training using gradient descent. However, making a “hard” selection from a categorical distribution is a non-differentiable operation that would generally prevent gradients from being backpropagated through the neural network.

In order to allow for updating the probabilities through gradient descent, the system selects the input connections using a technique that still allows for gradient computations. For example, for each node and for each input port of the respective logic gate represented by the node, the system can select an input connection from the respective set of input connections for the input port using a Gumbel-Softmax approximation of the probability distribution for the input port.

The system processes the training set of circuit inputs in the training example using the circuit neural network with each node receiving input from the selected input connections for the input ports of the logic gate represented by the node to generate a predicted of set of circuit outputs (step 406).

After performing steps 404 and 406 for all of the training examples, the system updates, through gradient descent, the probability distributions for the respective probability distributions for the input ports of the nodes of the neural network (step 408).

In particular, the system can perform this updating using gradients of an objective that measures, for each training example, the error between (i) the target set of circuit outputs and (ii) the predicted set of circuit outputs. More specifically, the system backpropagates the gradients of the objective in order to determine a respective update for the probability distributions for the input ports of some or all of the nodes in the neural network.

As described above, when the system uses the Gumbel-Softmax approximation when selecting the input connections, the system can compute gradients by backpropagating gradients through the Gumbel-Softmax approximations of the probability distributions for the input ports.

By repeatedly updating the parameters by performing the process 400, the system increases the fidelity of the circuit neural network (and therefore the circuit design) with respect to the specification.

Because the system trains the circuit neural network on randomly sampled batches of rows of the truth table given by the specification, the specification need not be complete, and unlike a classical specification, can even be stochastic in nature where some rows of the truth table are more probable than others. That is, the system can sample rows of the truth table to be trained on in accordance with a probability distribution that is non-uniform, i.e., assigns higher probabilities to certain rows, e.g., that have been identified as representing inputs for which it is more important to ensure that the logic circuit generates the correct output.

Additionally, when learning a circuit from specification using the process 400, it is possible to set the target accuracy to any value achievable by the circuit neural network. That is, the system can terminate the training whenever the initial design represented by the circuit neural network achieves the target accuracy. This provides an easy way to explicitly control the tradeoff between accuracy and efficiency and automatically generate a broad set of designs along its Pareto curve more tractably than hand-designing them.

The description above generally describes the system 100 generating a single final design in response to receiving a given specification.

Optionally, the system 100 can instead generate multiple initial designs by (i) initializing multiple different circuit neural networks with different architectures, e.g., with different numbers of layers, different numbers of nodes per layer, or with different nodes representing different types of logic gates and (ii) using each initialized circuit neural network to generate a respective initial design.

The system can then optimize each different initial design to generate multiple final designs. A circuit designer or an automated process can then select one of the multiple final designs for fabrication.

Optionally, the system can augment the set of multiple final designs by optimizing each initial design using multiple different objectives that place different importance on different hardware properties.

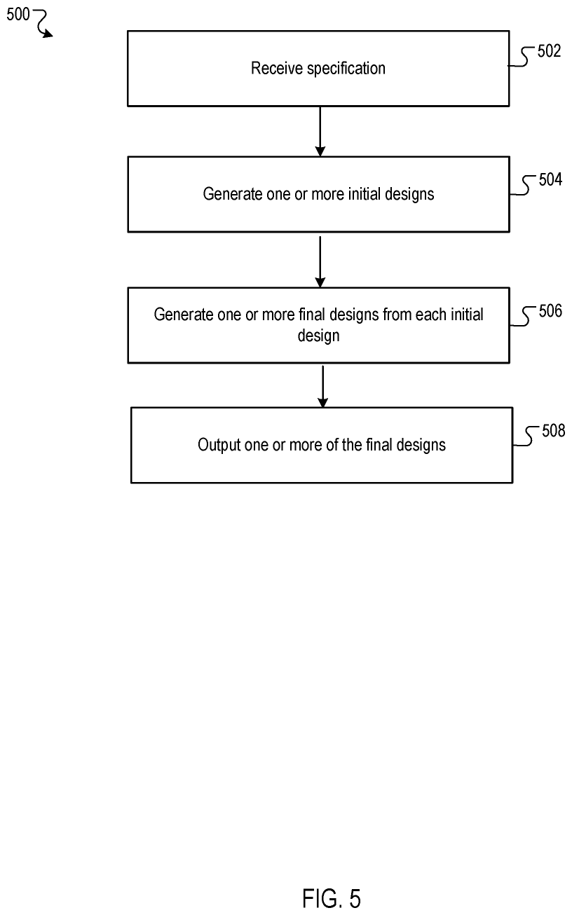

An example of this is described below with reference to FIG. 5.

FIG. 5 is a flow diagram of an example process 500 for generating multiple different circuit designs from a given specification. For convenience, the process 500 will be described as being performed by a system of one or more computers located in one or more locations. For example, a circuit design system, e.g., the circuit design system 100 of FIG. 1, appropriately programmed, can perform the process 500.

The system receives the specification (step 502).

The system generates one or more initial designs for the specification (step 504).

For example, when the system generates a single design, the system can generate the design by training a single instance of a circuit neural network as described above.

When the system generates multiple designs, the system can (i) initialize multiple different circuit neural networks with different architectures, e.g., with different numbers of layers, different numbers of nodes per layer, or with different nodes representing different types of logic gates and (ii) use each initialized circuit neural network to generate a respective initial design, i.e., by training each initialized circuit neural network using the same specification and then determining a respective initial design using each of the trained neural networks.

In some cases, the system can augment the set of initial designs with one or more human-generated designs, one or more designs generated using another system, or both. For example, the system can obtain one or more designs that a human or another system has determined sufficiently satisfy the specification, e.g., the truth table in the specification.

The system generates one or more final designs from each initial design (step 506).

For example, when the system generates a single final design from each initial design, the system can generate the final design by performing an optimization on an objective as described above.

When the system generates multiple final designs from a given initial design, the system can optimize each initial design using multiple different objectives that place different importance on different hardware properties.

The system outputs one or more of the final designs (step 508). For example, the system can output all of the final designs for presentation to a user to allow the user to select the design that will be used for fabrication. As another example, the system can output all of the final designs to another system that selects the design that will be used for fabrication. As yet anther example, the system can select one of the final designs, e.g., one that best satisfied a specified final objective, and output the selected final design, e.g., for presentation to a user or for fabrication.

This specification uses the term “configured” in connection with systems and computer program components. For a system of one or more computers to be configured to perform particular operations or actions means that the system has installed on it software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non transitory storage medium for execution by, or to control the operation of, data processing apparatus. The computer storage medium can be a machine-readable storage device, a machine-readable storage substrate, a random or serial access memory device, or a combination of one or more of them.

Alternatively or in addition, the program instructions can be encoded on an artificially generated propagated signal, e.g., a machine-generated electrical, optical, or electromagnetic signal, that is generated to encode information for transmission to suitable receiver apparatus for execution by a data processing apparatus.

The term “data processing apparatus” refers to data processing hardware and encompasses all kinds of apparatus, devices, and machines for processing data, including by way of example a programmable processor, a computer, or multiple processors or computers. The apparatus can also be, or further include, special purpose logic circuitry, e.g., an FPGA (field programmable gate array) or an ASIC (application specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program, which may also be referred to or described as a program, software, a software application, an app, a module, a software module, a script, or code, can be written in any form of programming language, including compiled or interpreted languages, or declarative or procedural languages; and it can be deployed in any form, including as a stand alone program or as a module, component, subroutine, or other unit suitable for use in a computing environment. A program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub programs, or portions of code. A computer program can be deployed to be executed on one computer or on multiple computers that are located at one site or distributed across multiple sites and interconnected by a data communication network.

In this specification, the term “database” is used broadly to refer to any collection of data: the data does not need to be structured in any particular way, or structured at all, and it can be stored on storage devices in one or more locations. Thus, for example, the index database can include multiple collections of data, each of which may be organized and accessed differently.

Similarly, in this specification the term “engine” is used broadly to refer to a software-based system, subsystem, or process that is programmed to perform one or more specific functions. Generally, an engine will be implemented as one or more software modules or components, installed on one or more computers in one or more locations. In some cases, one or more computers will be dedicated to a particular engine; in other cases, multiple engines can be installed and running on the same computer or computers.

The processes and logic flows described in this specification can be performed by one or more programmable computers executing one or more computer programs to perform functions by operating on input data and generating output. The processes and logic flows can also be performed by special purpose logic circuitry, e.g., an FPGA or an ASIC, or by a combination of special purpose logic circuitry and one or more programmed computers.

Computers suitable for the execution of a computer program can be based on general or special purpose microprocessors or both, or any other kind of central processing unit. Generally, a central processing unit will receive instructions and data from a read only memory or a random access memory or both. The essential elements of a computer are a central processing unit for performing or executing instructions and one or more memory devices for storing instructions and data. The central processing unit and the memory can be supplemented by, or incorporated in, special purpose logic circuitry. Generally, a computer will also include, or be operatively coupled to receive data from or transfer data to, or both, one or more mass storage devices for storing data, e.g., magnetic, magneto optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer readable media suitable for storing computer program instructions and data include all forms of non volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser. Also, a computer can interact with a user by sending text messages or other forms of message to a personal device, e.g., a smartphone that is running a messaging application, and receiving responsive messages from the user in return.

Data processing apparatus for implementing machine learning models can also include, for example, special-purpose hardware accelerator units for processing common and compute-intensive parts of machine learning training or production, i.e., inference, workloads.

Machine learning models can be implemented and deployed using a machine learning framework, e.g., a TensorFlow framework or a Jax framework.

Embodiments of the subject matter described in this specification can be implemented in a computing system that includes a back end component, e.g., as a data server, or that includes a middleware component, e.g., an application server, or that includes a front end component, e.g., a client computer having a graphical user interface, a web browser, or an app through which a user can interact with an implementation of the subject matter described in this specification, or any combination of one or more such back end, middleware, or front end components. The components of the system can be interconnected by any form or medium of digital data communication, e.g., a communication network. Examples of communication networks include a local area network (LAN) and a wide area network (WAN), e.g., the Internet.

The computing system can include clients and servers. A client and server are generally remote from each other and typically interact through a communication network. The relationship of client and server arises by virtue of computer programs running on the respective computers and having a client-server relationship to each other. In some embodiments, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

Aspects and embodiments of the disclosed subject matter may be as set out in the following numbered clauses:

Clause 1. A method performed by one or more computers, the method comprising:
receiving a specification for a logic circuit;
initializing a circuit neural network, the circuit neural network comprising a sequence of layers, each layer comprising one or more nodes, each node in each layer representing a respective logic gate that has one or more input ports and one or more output ports, wherein initializing the circuit neural network comprises, for each node, initializing a respective probability distribution over a respective set of input connections for each input port of the respective logic gate represented by the node;
training the circuit neural network using the specification to update the respective probability distributions for the input ports of the logic gates represented by the nodes of the neural network; and
determining, based on the updated probability distributions for the nodes of the neural network, an initial design for the logic circuit that satisfies the specification of the logic circuit.

Clause 2. The method of clause 1, wherein determining, based on the updated probability distributions for the input nodes of the neural network, an initial design for the logic circuit comprises:
for each node and for each input port of the respective logic gate represented by the node, selecting an input connection from the respective set of input connections for the input port using the updated probability distribution for the input port; and
generating the initial design, wherein (i) the initial design includes each respective logic gate that was selected as an input connection for at least one input port of at least one other logic gate and (ii) for each logic gate in the initial design, each input port of the logic gate is connected in the initial design to the selected input connection for the input port.

Clause 3. The method of clause 2, wherein selecting an input connection from the respective set of input connections for the input port using the updated probability distribution for the input port comprises:
selecting, as the input connection for the respective logic gate in the initial design, the input connection from the respective set of input connections that has a highest probability in the updated probability distribution for the input port.

Clause 4. The method of any preceding clause, wherein, for each node in a first layer of the sequence of layers, the respective set of input connections for the logic gate represented by the node includes each of a set of circuit inputs to the logic circuit.

Clause 5. The method of clause 4, wherein, for each node in each layer after the first layer of the sequence of layers, the respective set of input connections for the logic gate represented by the node includes the output ports of the respective logic gates represented by each node in one or more layers that precede the layer in the sequence.

Clause 6. The method of clause 5, wherein, for each node in each layer after the first layer of the sequence of layers, the respective set of input connections for the logic gate represented by the node include each of the set of circuit inputs to the logic circuit.

Clause 7. The method of any preceding clause, wherein each node in the circuit neural network represents a same type of logic gate.

Clause 8. The method of any one of clauses 1-6, wherein two or more of the nodes in the circuit neural network represent different types of logic gate.

Clause 9. The method of any preceding clause, wherein each node is configured to receive a respective input corresponding to each input port of the respective logic gate represented by the node and to apply, to the respective inputs, a continuous function that expresses the respective logic operation performed by the respective logic gate to generate an output.

Clause 10. The method of clause 9, wherein training the circuit neural network using the specification to update the respective probability distributions for the input ports of the nodes of the neural network comprises, at each of a plurality of training iterations:
selecting, using the specification, one or more training examples, each training example comprising a training set of circuit inputs and a target set of circuit outputs;
for each training example:
   selecting, for each node and for each input port of the respective logic gate represented by the node, an input connection from the respective set of input connections for the input port using the probability distribution for the input port; and
   processing the training set of circuit inputs in the training example using the circuit neural network with each node receiving input from the selected input connections for the input ports of the logic gate represented by the node to generate a predicted of set of circuit outputs; and
updating, through gradient descent, the probability distributions for the respective probability distributions for the input ports of the nodes of the neural network using gradients of an objective that measures, for each training example, an error between the target set of circuit outputs and the predicted set of circuit outputs.

Clause 11. The method of clause 10, wherein selecting, for each node and for each input port of the respective logic gate represented by the node, an input connection from the respective set of input connections for the input port using the probability distribution for the input port comprises:
selecting, for each node and for each input port of the respective logic gate represented by the node, an input connection from the respective set of input connections for the input port using a Gumbel-Softmax approximation of the probability distribution for the input port; and
updating, through gradient descent, the probability distributions for the respective probability distributions for the input ports of the nodes of the neural network using gradients comprises:
computing gradients by backpropagating gradients through the Gumbel-Softmax approximations of the probability distributions for the input ports.

Clause 12. The method of clause 10 or clause 11, wherein the specification defines a truth table for the logic circuit and each training example corresponds to a respective row of the truth table.

Clause 13. The method of any preceding clause, further comprising:
generating a final design for the logic circuit from the initial design.

Clause 14. The method of clause 13, wherein:
generating a final design for the logic circuit from the initial design comprises:
performing an optimization of an objective starting from the initial design.

Clause 15. The method of clause 14, wherein performing the optimization comprises optimizing over sequences of rewrite actions applied to the initial design.

Clause 16. The method of clause 15, wherein each rewrite action in the sequence is selected from a set of possible rewrite actions.

Clause 17. The method of clause 15 or clause 16, wherein performing the optimization comprises optimizing using one of: simulated annealing, a genetic algorithm, or Bayesian optimization.

Clause 18. The method of clause 15 or clause 16, wherein performing the optimization comprises optimizing using a tree search over a state tree of states of the design that is traversed by performing rewrite actions on the design.

Clause 19. The method of clause 18, wherein the tree search is guided by outputs of a neural network that receives an input comprising a current state of the design and generates an output comprising a probability distribution over a set of possible rewrite actions.

Clause 20. The method of any preceding clause when dependent on clause 14, wherein the objective measures one or more of:
power consumption of a circuit having the design;
area of a circuit having the design; or
performance of a circuit having the design.

Clause 21. The method of any preceding clause when dependent on clause 13, further comprising:
providing data specifying the final design for use in fabricating an integrated circuit that has the final design.

Clause 22. The method of any preceding clause when dependent on clause 13, further comprising: fabricating an integrated circuit that has the final design.

Clause 23. The method of any preceding clause, further comprising:
receiving initialization data, wherein the initialization data specifies a number of layers in the circuit neural network, a number of nodes in each layer, and a respective gate type for each logic gate represented by each of the nodes of the circuit neural network; wherein
initializing a circuit neural network comprises initializing the circuit neural network to have the specified number of layers, the specified number of nodes in each layer, and with each node in each layer representing a logic gate having the respective specified gate type for the logic gate.

Clause 24. An integrated circuit having a design that has been determined by performing the respective operations of any preceding clause.

Clause 25. A system comprising one or more computers and one or more storage devices storing instructions that are operable, when executed by the one or more computers, to cause the one or more computers to perform the operations of the respective method of any one of clauses 1-23.

Clause 26. One or more computer storage media encoded with instructions that, when executed by one or more computers, cause the one or more computers to perform the operations of the respective method of any one of clauses 1-23.

1. A method performed by one or more computers, the method comprising:
receiving a specification for a logic circuit;
initializing a circuit neural network, the circuit neural network comprising a sequence of layers, each layer comprising one or more nodes, each node in each layer representing a respective logic gate that has one or more input ports and one or more output ports, wherein initializing the circuit neural network comprises, for each node, initializing a respective probability distribution over a respective set of input connections for each input port of the respective logic gate represented by the node;
training the circuit neural network using the specification to update the respective probability distributions for the input ports of the logic gates represented by the nodes of the neural network; and
determining, based on the updated probability distributions for the nodes of the neural network, an initial design for the logic circuit that satisfies the specification of the logic circuit.

2. The method of claim 1, wherein determining, based on the updated probability distributions for the input nodes of the neural network, an initial design for the logic circuit comprises:
for each node and for each input port of the respective logic gate represented by the node, selecting an input connection from the respective set of input connections for the input port using the updated probability distribution for the input port; and
generating the initial design, wherein (i) the initial design includes each respective logic gate that was selected as an input connection for at least one input port of at least one other logic gate and (ii) for each logic gate in the initial design, each input port of the logic gate is connected in the initial design to the selected input connection for the input port.

3. The method of claim 2, wherein selecting an input connection from the respective set of input connections for the input port using the updated probability distribution for the input port comprises:
selecting, as the input connection for the respective logic gate in the initial design, the input connection from the respective set of input connections that has a highest probability in the updated probability distribution for the input port.

4. The method of claim 1, wherein, for each node in a first layer of the sequence of layers, the respective set of input connections for the logic gate represented by the node includes each of a set of circuit inputs to the logic circuit.

5. The method of claim 4, wherein, for each node in each layer after the first layer of the sequence of layers, the respective set of input connections for the logic gate represented by the node includes the output ports of the respective logic gates represented by each node in one or more layers that precede the layer in the sequence.

6. The method of claim 5, wherein, for each node in each layer after the first layer of the sequence of layers, the respective set of input connections for the logic gate represented by the node include each of the set of circuit inputs to the logic circuit.

7. The method of claim 1, wherein each node in the circuit neural network represents a same type of logic gate.

8. The method of claim 1, wherein two or more of the nodes in the circuit neural network represent different types of logic gate.

9. The method of claim 1, wherein each node is configured to receive a respective input corresponding to each input port of the respective logic gate represented by the node and to apply, to the respective inputs, a continuous function that expresses the respective logic operation performed by the respective logic gate to generate an output.

10. The method of claim 9, wherein training the circuit neural network using the specification to update the respective probability distributions for the input ports of the nodes of the neural network comprises, at each of a plurality of training iterations:
selecting, using the specification, one or more training examples, each training example comprising a training set of circuit inputs and a target set of circuit outputs;
for each training example:
selecting, for each node and for each input port of the respective logic gate represented by the node, an input connection from the respective set of input connections for the input port using the probability distribution for the input port; and
processing the training set of circuit inputs in the training example using the circuit neural network with each node receiving input from the selected input connections for the input ports of the logic gate represented by the node to generate a predicted of set of circuit outputs; and
updating, through gradient descent, the probability distributions for the respective probability distributions for the input ports of the nodes of the neural network using gradients of an objective that measures, for each training example, an error between the target set of circuit outputs and the predicted set of circuit outputs.

11. The method of claim 10, wherein selecting, for each node and for each input port of the respective logic gate represented by the node, an input connection from the respective set of input connections for the input port using the probability distribution for the input port comprises:
selecting, for each node and for each input port of the respective logic gate represented by the node, an input connection from the respective set of input connections for the input port using a Gumbel-Softmax approximation of the probability distribution for the input port; and
updating, through gradient descent, the probability distributions for the respective probability distributions for the input ports of the nodes of the neural network using gradients comprises:
computing gradients by backpropagating gradients through the Gumbel-Softmax approximations of the probability distributions for the input ports.

12. The method of claim 10, wherein the specification defines a truth table for the logic circuit and each training example corresponds to a respective row of the truth table.

13. The method of claim 1, further comprising:
generating a final design for the logic circuit from the initial design.

14. The method of claim 13, wherein:
generating a final design for the logic circuit from the initial design comprises:
performing an optimization of an objective starting from the initial design.

15. The method of claim 14, wherein performing the optimization comprises optimizing over sequences of rewrite actions applied to the initial design.

16. The method of claim 15, wherein each rewrite action in the sequence is selected from a set of possible rewrite actions.

17. The method of claim 15, wherein performing the optimization comprises optimizing using one of: simulated annealing, a genetic algorithm, or Bayesian optimization.

18. The method of claim 15, wherein performing the optimization comprises optimizing using a tree search over a state tree of states of the design that is traversed by performing rewrite actions on the design.

19. The method of claim 18, wherein the tree search is guided by outputs of a neural network that receives an input comprising a current state of the design and generates an output comprising a probability distribution over a set of possible rewrite actions.

20. The method of claim 14, wherein the objective measures one or more of:
power consumption of a circuit having the design;
area of a circuit having the design; or
performance of a circuit having the design.

21. The method of claim 13, further comprising:
providing data specifying the final design for use in fabricating an integrated circuit that has the final design.

22. The method of claim 13, further comprising: fabricating an integrated circuit that has the final design.

23. The method of claim 1, further comprising:
receiving initialization data, wherein the initialization data specifies a number of layers in the circuit neural network, a number of nodes in each layer, and a respective gate type for each logic gate represented by each of the nodes of the circuit neural network; wherein
initializing a circuit neural network comprises initializing the circuit neural network to have the specified number of layers, the specified number of nodes in each layer, and with each node in each layer representing a logic gate having the respective specified gate type for the logic gate.

24. An integrated circuit having a design that has been determined by performing operations comprising:
receiving a specification for a logic circuit;
initializing a circuit neural network, the circuit neural network comprising a sequence of layers, each layer comprising one or more nodes, each node in each layer representing a respective logic gate that has one or more input ports and one or more output ports, wherein initializing the circuit neural network comprises, for each node, initializing a respective probability distribution over a respective set of input connections for each input port of the respective logic gate represented by the node;
training the circuit neural network using the specification to update the respective probability distributions for the input ports of the logic gates represented by the nodes of the neural network; and
determining, based on the updated probability distributions for the nodes of the neural network, an initial design for the logic circuit that satisfies the specification of the logic circuit.

25. A system comprising one or more computers and one or more storage devices storing instructions that are operable, when executed by the one or more computers, to cause the one or more computers to perform operations comprising:
receiving a specification for a logic circuit;
initializing a circuit neural network, the circuit neural network comprising a sequence of layers, each layer comprising one or more nodes, each node in each layer representing a respective logic gate that has one or more input ports and one or more output ports, wherein initializing the circuit neural network comprises, for each node, initializing a respective probability distribution over a respective set of input connections for each input port of the respective logic gate represented by the node;
training the circuit neural network using the specification to update the respective probability distributions for the input ports of the logic gates represented by the nodes of the neural network; and
determining, based on the updated probability distributions for the nodes of the neural network, an initial design for the logic circuit that satisfies the specification of the logic circuit.

26. (canceled)
